(19) United States
(12) Patent Application Publication
(10) Pub. No.: US 2009/0146553 A1
(43) Pub. Date: Jun. 11, 2009

(54) Organic Electroluminescence Element, Method for Manufacturing Same, and Display Device

(75) Inventors: Yuko Abe, Tokyo (JP); Eiichi Kitazume, Tokyo (JP); Noriko Morikawa, Tokyo (JP)

Correspondence Address: SQUIRE, SANDERS & DEMPSEY L.L.P., 1 MARITIME PLAZA, SUITE 300, SAN FRANCISCO, CA, 94111, US

(73) Assignee: Toppan Printing Co., Ltd., Tokyo (JP)

(21) Appl. No.: 12/242,600

(22) Filed: Sep. 30, 2008

(30) Foreign Application Priority Data
Dec. 5, 2007 (JP) 2007-315087

(51) Int. Cl. H01J 1/62; B05D 5/06

(52) U.S. Cl. 313/504; 427/66

(57) ABSTRACT

An organic EL element has a first electrode, a second electrode facing the first electrode, and a luminescence medium layer including a carrier transport layer and an organic luminescence layer provided between the electrodes. The carrier transport layer is an inorganic oxide layer obtained by performing an oxidation treatment after forming the layer.

### CROSS REFERENCE TO RELATED APPLICATION

This application is based on and claims the benefit of priority from the Japanese Patent Application number 2007-315087, filed on Dec. 5, 2007; the entire contents of which are incorporated herein by reference.

### BACKGROUND OF THE INVENTION

1. Field of the Invention

The present invention relates to an organic electroluminescence element (referred to hereinbelow as “organic EL element”), a method for manufacturing same, and a display device.

2. Description of the Related Art

In an organic EL element, where a voltage is applied to an electrically conductive luminescence medium layer, electrons and holes injected in an organic luminescence layer located within the luminescence medium layer recombinate and energy is emitted. A luminescence material located in the organic luminescence layer is excited by receiving this energy and thereafter releases the energy when it returns to the ground state, thereby emitting light. A first electrode and a second electrode are provided on both sides of the luminescence medium layer to apply a voltage to the organic medium layer, and at least one of the electrodes is translucent to allow the light from the luminescence layer to be taken to the outside. A structure obtained by successively laminating a translucent first electrode, a luminescence medium layer, and a second electrode on a translucent substrate is an example of such organic EL element structure. A configuration in which the first electrode formed on the substrate is used as an anode, and the second electrode formed on the luminescence medium layer is used as a cathode will be explained below.

Examples of materials used in the organic luminescence medium layer include copper phthalocyanine for a hole injection layer, N,N′-di(1-napthyl)-N,N′-diphenyl-1,1′-biphenyl-4,4′-diamine for a hole transport layer, and tris(8-quinolinol)aluminum for a luminescence layer.

In order to increase the emission efficiency, in most organic EL elements, an electron transport layer and an electron injection layer are appropriately and selectively provided between the organic luminescence layer and cathode, in addition to the hole transport layer and hole injection layer provided between the anode and organic luminescence layer. These hole transport layer, hole injection layer, electron transport layer, and electron injection layer are called carrier transport layers. These carrier transport layers, organic luminescence layer, and also a hole blocking layer, an electron blocking layer, and an insulating layer are collectively called a luminescence medium layer. When the luminescence medium layer has the above-described configuration and all the substances demonstrating functions (called luminescence medium materials) are small-molecular compounds, each layer can be laminated to a thickness of about 1-100 nm, for example, by a vapor deposition method such as a resistance heating method.

By contrast, there are organic EL elements using polymer materials in the organic luminescence layer (referred to hereinbelow as “polymer organic EL elements”). Examples of materials for the luminescence layer include materials obtained by dissolving a small-molecular luminescence colorant in a polymer material such as polystyrene, polymethyl methacrylate, and polyvinyl carbazole and polymer luminescence materials such as polyphenylene vinylene derivatives (PPV) and polyalkylfluorene derivatives (PAF). A luminescence layer can be produced by a wet method such as a coating method and a printing method by dissolving or dispersing the polymer materials in a solvent. The advantage of such a process is that the film can be formed under an atmospheric pressure and the equipment cost can be reduced by comparison with that in the case of organic EL elements using the aforementioned small-molecular materials.

In a polymer organic EL element, a hole transport layer is typically provided to lower the applied voltage. In a representative example, a hole transport layer is formed using an ink composed of a polymer material obtained by dispersing an association of donor molecules and acceptor molecules in water, and such a hole transport layer is known to demonstrate an excellent charge injection characteristic. However, the problem is that because a hole transport layer composed of a polymer material has a high electric resistance, a high load is applied to the film in a high-voltage area, the material itself is degraded, and the luminance and current density are decreased. Thus, organic EL elements using a hole transport layer composed of a polymer material have poor resistance and demonstrate deterioration of light emission characteristics and shortening of life time.

It has also been suggested to use inorganic oxides such as transition metal oxides or oxide semiconductors for carrier transport layers (Japanese Patent Applications Laid-open No. 5-41285, 2000-68065, 2000-215985, 2006-114521, 2006-114759, 2006-155978, and 9-63771). Carrier transport layers composed of such inorganic oxides are superior to the carrier transport layers composed of polymer materials in terms of endurance and make it possible to obtain long service life and stable characteristics in a high-luminance range. However, oxygen defects tend to occur easily in these inorganic oxides when the films thereof are formed by vacuum vapor deposition or sputtering. When the number of oxygen defects in the film is large, electric conductivity increases. The resultant problems include the decreased electric resistance of the film, excessive carrier flow, decreased light emission efficiency of the organic EL element, and the occurrence of emission leak. Other problems include the decrease in transmissivity of the film and decrease in emission luminance of the organic EL element. Conversely, when the number of oxygen defects is too small, the increase in drive voltage becomes a concern.

Yet another problem is that inorganic oxides constituting the carrier transport layers have poor wettability with organic solvents employed for dissolving the luminescent material that is to be laminated on the inorganic oxides. Where wettability is poor, peeling easily occurs. Other resultant drawbacks include the decrease in pattern sharpness of the fabricated organic EL element, increase in unevenness, poor adhesion, and occurrence of pinholes.

Thus, in the organic EL elements having a carrier transport layer composed of an inorganic oxide, it is necessary to perform arbitrary control of electric conductivity or transmissivity thereof and improve wettability.

The present invention has been created with consideration for the above-described problems and it is an object thereof to provide a highly reliable organic EL element in which electric conductivity or transmissivity of a carrier transport layer composed of an inorganic oxide can be adjusted and wettability of the inorganic oxide layer is improved, thereby making it possible to manufacture the element by a simple process.

### SUMMARY OF THE INVENTION

According to the first aspect of the present invention, there is provided an organic EL element including a first electrode; a second electrode facing the first electrode; and a luminescence medium layer having a carrier transport layer and an organic luminescence layer provided between the electrodes; wherein the carrier transport layer is an inorganic oxide layer obtained by performing an oxidation treatment after forming the layer.

According to another aspect of the present invention, there is provided a method for manufacturing an organic EL element according to the first aspect, the method including a step of forming an inorganic oxide layer as the carrier transport layer and a step of performing oxidation treatment of the inorganic oxide layer.

According to another aspect of the present invention, there is provided a display device including the organic EL element according to the first aspect.

### BRIEF DESCRIPTION OF THE DRAWINGS

FIG. 1 is a cross-sectional view illustrating an example of the organic EL element structure in accordance with the present invention;

FIG. 2 is a cross-sectional view illustrating another example of the organic EL element structure in accordance with the present invention; and

FIG. 3 is a schematic drawing of a relief printing device for use in the manufacture of the organic EL element in accordance with the present invention.

### DETAILED DESCRIPTION OF THE INVENTION

An embodiment of the present invention will be described below with reference to the appended drawings. The drawings referred to in the explanation of the embodiment serve to illustrate the features of the present invention, and the size, thickness, and dimensions of components shown in the figure differ from the actual ones. Further, the present invention is not limited thereto.

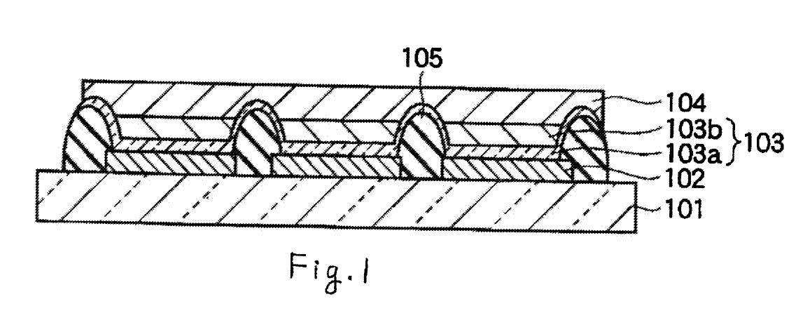

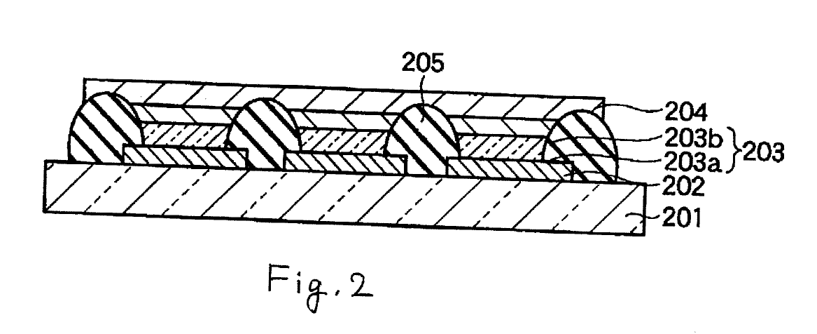

An example of the organic EL element in accordance with the present invention will be explained below with reference to FIG. 1 and FIG. 2.

FIG. 1 is a cross-sectional view illustrating an example of the organic EL element structure in accordance with the present invention. FIG. 2 is a cross-sectional view illustrating another example of the organic EL element structure in accordance with the present invention. The corresponding numerals denote identical structural units (for example, 103a and 203a which are hole transport layers). The explanation below will be focused on FIG. 1. Where a side of a substrate 101 serves as a display side and a translucent first electrode in accordance with the present invention is provided on the substrate, it is preferred that the substrate 101 be translucent. A material of the translucent substrate 101 is not limited provided that this material is translucent and has a certain strength. Specific examples of suitable substrates include a glass substrate and a plastic film or sheet. Where a thin glass substrate with a thickness of 0.2-1 mm is used, a thin organic EL element with a very high barrier ability can be fabricated.

A transparent electrically conductive layer forming a translucent first electrode 102 is not particularly limited provided that it is from an electrically conducive substance that can form a transparent or semitransparent electrode. When the translucent electrode is an anode, examples of suitable transparent electrically conductive substance include a composite oxide of indium and tin (abbreviated hereinbelow as ITO), a composite oxide of indium and zinc (abbreviated hereinbelow as IZO), tin oxide, zinc oxide, indium oxide, and a composite oxide of zinc and aluminum.

ITO can be preferably used as the transparent electrically conductive substance because of low resistance, high resistance to solvents, and high transparency thereof, and an ITO layer can be produced as a translucent first electrode 102 by a vapor deposition method or sputtering method on the translucent substrate 101. Further, because an oxide can be formed by coating a precursor such as indium octylate or acetone indium on a base material and then pyrolyzing the coating, the translucent first electrode 102 can be also formed by the coating-pyrolysis method. Alternatively, a metal such as aluminum, gold, and silver that is vapor deposited to obtain a semi-transparent state can be used as the translucent first electrode 102. Further, an organic semiconductor such as polyaniline can be also used.

If necessary, the translucent first electrode 102 may be etched and patterned or surface activation thereof may be performed by UV treatment, plasma treatment, or the like.

When an organic EL element is manufactured for a display suitable for matrix display, the translucent first electrodes are formed as stripes and second electrodes 104 that are formed to face the first electrodes via the luminescence medium layer are formed as stripes that cross the translucent first electrodes 102, thereby enabling the matrix display of a system in which the intersections of the stripes emit light. Active matrix display can be also attained by forming thin-film transistors corresponding to pixels on the substrate 101 and providing pixel electrodes (translucent electrodes) corresponding to the pixels so that they are conductively connected thereto.

When the first electrode 102 is patterned, large peaks and valleys are formed at the end portions of each pattern, and discontinuous coverage is sometimes observed in the luminescence medium layer laminated from above. As a result, there is a risk of a short circuit occurring between the first electrode 102 and second electrode 104. Accordingly, it is preferred that the end portions of the patterned first electrode 102 be covered with an insulating resin or the like. The end portions can be covered by imparting photosensitivity to a resin composition such as a polyimide, an acryl, or a polyurethane, coating the composition so as to cover the end portion, exposing via a mask, and developing. In the organic EL element shown in FIG. 1, an insulating rib 105 composed of an insulating resin is provided between the second electrode 104 and the patterned translucent first electrode 102, so as to cover the end portions of adjacent patterns. This insulating rib is similarly provided on the second electrode.

Where the height of the insulating rib 105 composed of the insulating resin exceeds a predetermined value, for example, 0.5 μm to 1.5 μm, the rib serves to prevent color mixing when organic luminescence layers containing organic luminescence materials capable of emitting light of different colors are formed in the adjacent luminescence regions.

The luminescence medium layer 103 of the organic EL element in accordance with the present invention is not limited to the two-layer structure composed of a hole transport layer 103a including an inorganic oxide and an organic luminescence layer 103b as shown in FIG. 1, and the effect of the present invention can be also obtained with structures that additionally include a hole injection layer, a hole blocking layer, an electron transport layer, an electron injection layer, an electron blocking layer, and an insulating layer. These layers may have random thickness, but it is preferred that a thickness of each layer be 0.1 nm to 200 nm and a total thickness of the luminescence medium layer be 50 nm to 500 nm.

Furthermore, carrier transport layers such as a hole injection layer, an electron transport layer, and an electron injection layer, rather than only the hole transport layer, can be also formed from inorganic oxides. Among them, forming the hole transport layer or hole injection layer from an inorganic oxide is especially preferred because excellent endurance is attached, and stable characteristics in a high-luminance region and long service life can be obtained.

Transition metal oxides or oxynitrides and oxide semiconductors can be used as the inorganic oxides, and transition metal oxides are especially preferred. This is because transition metals have a plurality of oxidation numbers in transition metal oxides and, therefore, a plurality of electric potential levels can be obtained, injection of holes is facilitated, and the drive voltage can be reduced.

The thickness of the carrier transport layer including the inorganic oxide is not particularly limited, but the preferred thickness is 0.1 nm to 200 nm. A thickness of 0.1 nm to 70 nm is especially preferred because the increase of drive voltage can be prevented. Where the carrier transport layer is too thick, the decrease in efficiency caused by a drop in voltage or decrease in transmittance cannot be avoided. Where the carrier transport layer is too thin, the effect of carrier transport is reduced. As a result, in this case, a voltage drop also occurs. In particular, when the insulating ability of the inorganic oxide forming the carrier transport layer is high, good carrier transport layer can be obtained by forming a film with a thickness within a range from 0.1 nm to 10 nm.

When the carrier transport layer composed of the inorganic oxide is a hole transport layer, the layer is almost transparent in a visible light range if the band gap is equal to or more than 3.0 eV. Therefore, excellent EL characteristics such as chromaticity, luminance, and emission efficiency can be obtained.

Examples of suitable transition metal oxides include oxides of chromium (Cr), tungsten (W), vanadium (V), niobium (Nb), tantalum (Ta), molybdenum (Mo), titanium (Ti), zirconium (Zr), hafnium (Hf), scandium (Sc), yttrium (Y), manganese (Mn), iron (Fe), ruthenium (Ru), osmium (Os), cobalt (Co), nickel (Ni), copper (Cu), zinc (Zn), and cadmium (Cd). Furthermore, in addition to oxides satisfying the stoichiometric ratio, partially oxidized transition metals and transition metal oxides in which part of oxygen is replaced with nitrogen may be also used.

The transition metal compound layer can be formed mainly by vacuum vapor deposition and sputtering. In particular, when the layer is formed using vacuum vapor deposition, the environment during vacuum vapor deposition becomes a reductive atmosphere. In the process of heating and sublimating in such atmosphere and depositing on a substrate, the transition metal oxide is easily reduced.

When a film of molybdenum trioxide MoO₃, which is a molybdenum oxide that can be advantageously used for the hole transport layer, is formed by a vacuum vapor deposition method, the reduced molybdenum oxide generates several oxides having a lower oxidation value, in addition to MoO₃, which is a hexavalent molybdenum oxide. Thus, a molybdenum trioxide layer containing a large number of oxygen defects can be obtained by mixing MoO₂, which is a tetravalent molybdenum oxide, and Mo₂O₃, which is a trivalent molybdenum oxide. Other advantages of molybdenum are derived from the possibility of obtaining a plurality of electric potential levels, as described above, because molybdenum is a polyvalent metal. However, when the number of oxygen defects is too large, the electric conductivity of the film becomes unnecessarily high and transmissivity decreases. Therefore, the number of oxygen defects has to be controlled.

Likewise, in vanadium oxide that also can be advantageously used for the hole transport layer, when a vanadium pentoxide (V₂O₅) film is formed by vacuum vapor deposition, the reduced vanadium oxides include V₂O₅, which is a pentavalent vanadium oxide and also several oxides that have a lower valence. Thus, a vanadium oxide layer containing a large number of oxygen defects is formed, this layer having a mixture of V₂O₄, which is a tetravalent vanadium oxide, and V₂O₃, which is a trivalent vanadium oxide, and the above-described problems are induced.

The electric conductivity of the hole transport layer 103a produces a large effect on final light emission characteristics. According to the present invention, by performing an oxidation treatment after forming a transmission metal oxide layer as the hole carrier layer 103a, it is possible to adjust freely the electric conductivity or transmissivity of the film and control the final light emission characteristic. A method for oxidation treatment is not particularly limited, and representative examples of such methods include oxygen plasma treatment, heat treatment under oxygen atmosphere, UV treatment, and injection of oxygen atoms and ions. Among them, an oxygen plasma treatment method, a method for thermal oxidation under oxygen atmosphere, and a UV treatment method are easy to implement and they have industrial utility.

In oxygen plasma, ions are generated and these ions, neutral molecules, and neutral atoms are ejected into a vacuum atmosphere. By causing the ions etc. to fall on the surface of a thin oxide film, it is possible to perform oxidation and repair oxygen defects. Further, when an organic substance has adhered to the surface of a thin oxide film, the surface is cleaned by the oxygen plasma, and wettability in subsequent lamination of an organic luminescence layer is increased.

In the method of oxidizing with oxygen plasma, the oxidation treatment is preferably carried out for 5 sec to 200 sec under an oxygen gas pressure of 0.1 Pa or 10 Pa and a power input of 10 W to 100 W. The conditions can be appropriately determined according to the thickness of oxide layer or degree of oxygen deficiency, thereby making it possible to inhibit freely the oxidation reaction.

With the thermal oxidation treatment under oxygen atmosphere, the oxidation reaction can be freely controlled by appropriately setting the reaction temperature, time, and atmosphere. Therefore, a carrier transport layer having the desired properties can be easily obtained. In this case, it is noteworthy that when the reaction temperature is too high, crystallization advances in the carrier transport layer that is formed to have an amorphous structure and this crystallization can cause a short circuit or dark spots. Further, where the crystallization advances in the carrier transport layer, when an organic layer is laminated by a wet method on the carrier transport layer, the crystallization causes unevenness or peeling and a uniform film is difficult to obtain. On the other hand, where the reaction temperature is too low, the oxidation reaction cannot proceed sufficiently.

The thermal oxidation treatment under oxygen atmosphere can be carried out under temperature conditions of from room temperature to 300° C., preferably from 100° C. to 250° C. The reaction time is, for example, 30 min to 3 h.

With the UV treatment method, the oxidation of inorganic oxide is advanced by active oxygen generated during UV treatment, and oxygen defects can be repaired. Where active oxygen comes into contact with the surface of an inorganic oxide layer containing oxygen defects, oxygen atoms are bonded to the oxygen defect portions and the oxidation reaction proceeds. As a result, the electric conductivity of the inorganic oxide can be decreased or transmissivity can be increased as described hereinabove.

Further, by performing the UV treatment, it is possible to decompose the organic substances that have adhered to the surface and improve wettability of the film. Ultraviolet radiation having high energy (254 nm, 185 nm) breaks bonds of organic substances that have adhered to the film surface and the organic substances are converted into free radicals or excited molecules of organic compounds. Further, ultraviolet radiation (185 nm) is absorbed by oxygen contained in the atmosphere, thereby generating ozone (O₃), and where ultraviolet radiation (254 nm) is absorbed by the ozone, the excited oxygen atoms are generated. The excited oxygen atoms have a strong oxidation capacity, react with the aforementioned free radicals or excited molecules of organic compounds, and produce CO₂, H₂O, and the like, thereby volatilizing and removing the organic substances that have adhered to the film surface. By removing extra organic compounds, it is possible to increase wettability of the film, and the increased wettability enables uniform formation of a film that will be subsequently deposited. Further, because the wettability is improved, a contact surface area with the subsequently formed film increases, thereby improving the interface adhesivity, which is important for obtaining good organic EL element properties.

Due to the cleaning effect of UV treatment, dark spots and short circuit (caused by crystallization of organic substances that have adhered to the surface) are reduced and display properties of the organic EL element are improved, namely, wettability is improved, film uniformity is increased, and interface adhesivity is improved. Furthermore, by controlling the electric conductivity or transmissivity of the film by the oxidation action, it is possible to adjust drive characteristics of the organic EL element. In addition, the aforementioned properties can be controlled to any state by changing the light quantity of a light source in the UV treatment, the distance between the light source and the irradiation film surface, and the irradiation time.

Low-pressure mercury lamps, high-pressure mercury lamps, and excimer lamps are used as light sources for UV treatment, and the present invention may use any of these light sources.

The hole transport layer 103a of the organic EL element preferably has an electric conductivity of 1×10⁻⁷ S/cm to 1 S/cm, more preferably an electric conductivity of 1×10⁻⁶ S/cm to 1×10⁻² S/cm. When the electric conductivity is too high, hole injection becomes excessive and light emission efficiency decreases. In addition, there is a probability of emission leak occurring due to electric current leak. When the electric conductivity is too low, the electric resistance of the film increases and voltage drop in the high-luminance region becomes significant.

FIG. 2 is a cross-sectional view illustrating another example of the organic EL element structure in accordance with the present invention. When the electric conductivity of the hole transport layer 103a in accordance with the present invention is sufficiently high, it is preferred that the inorganic oxide layer 103a be provided between insulating ribs 105 and that the hole transport layer 103a composed of the inorganic oxide layer be not provided continuously between the adjacent luminescence regions, as shown in FIG. 2. This is because such a configuration reliably prevents the light emission leak caused by electric current leak. On the other hand, by sufficiently controlling the electric conductivity of the hole transport layer 103a, it is possible to form the hole transport layer 103a composed of an inorganic oxide layer between the insulating ribs 105 and continuously on the insulating ribs 105 as shown in FIG. 1. In this case, the hole transport layer 103a composed of an inorganic oxide layer may be formed over the entire surface of the first electrode 102 and patterning of the hole transport layer 103a becomes unnecessary. Therefore, the production process is facilitated.

When the hole transport layer 103a composed of an inorganic oxide layer is provided between the insulating ribs 105, a pattern can be formed by forming an inorganic oxide over the entire surface of the first electrode 102 by sputtering or vapor deposition and then removing the unnecessary portions by photolithography or the like. Further, a film can be also formed according to the desired pattern shape by using a mask.

When a carrier transport layer other than the hole transport layer is taken as an inorganic oxide layer, organic materials that have been generally used as hole transport materials can be advantageously used for the hole transport layer 103a. Thus, examples of suitable small-molecular materials include copper phthalocyanine and derivatives thereof, 1,1-bis(4-di-p-tolylaminophenyl)cyclohexane, N,N′-diphenyl-N,N′-bis(3-methylphenyl)-1,1′-biphenyl-4,4′-diamine (TPD), triphenylamine derivatives, and other aromatic amines. The films of these materials can be formed by a dry process such as vacuum vapor deposition.

Further, a film can be also formed by a wet process by using a hole transport coating liquid prepared by dissolving or dispersing the above-described materials in an individual or mixed solvent such as toluene, xylene, acetone, anisole, methyl anisole, dimethyl anisole, ethyl benzoate, methyl benzoate, mesitylene, tetralin, amyl benzene, methyl ethyl ketone, methyl isobutyl ketone, cyclohexanone, methanol, ethanol, isopropyl alcohol, ethyl acetate, butyl acetate, cyclohexanol, and water.

Examples of polymer materials include polyaniline, polythiophene, polyvinyl carbazole, a mixture of poly(3,4-ethylenedioxythiophene) and polystyrenesulfonic acid, PPV derivatives, and PAF derivatives. Films of these hole transport materials can be formed by a wet process by using a hole transport coating liquid prepared by dissolving or dispersing the above-described materials in an individual or mixed solvent such as toluene, xylene, acetone, methyl ethyl ketone, methyl isobutyl ketone, cyclohexanone, methanol, ethanol, isopropyl alcohol, ethyl acetate, butyl acetate, cyclohexanol, and water.

These materials of the hole transport layer can be also advantageously used as materials for the hole injection layer.

Luminescent substances that have generally been used as organic luminescence material are suitable as luminescent substances for the organic luminescence layer 103b. For example, luminescent materials obtained by dissolving luminescence colorants of a coumarin system, a perylene system, a pyran system, an anthrone system, a porphylene system, a quinacridone system, an N,N′-dialkyl-substituted quinacridone system, naphthalimide system and an N,N′-diaryl-substituted pyrrolopyrrole system in a polymer such as polystyrene, polymethyl methacrylate, and polyvinyl carbazole, or polymer luminescent materials such as those of a PPV system, PAF system, or polyparaphenylene system can be used.

Films of these organic luminescence materials can be formed by a wet process by using an organic luminescence coating liquid prepared by dissolving or dispersing the organic luminescence materials in an individual or mixed solvent such as toluene, xylene, acetone, anisole, methyl anisole, dimethyl anisole, mesitylene, methyl ethyl ketone, methyl isobutyl ketone, cyclohexanone, methanol, ethanol, isopropyl alcohol, ethyl acetate, butyl acetate, and water. Aromatic solvents such as toluene, xylene, anisole, methyl anisole, dimethylanisole, ethyl benzoate, methyl benzoate, and mesitylene are especially good solvents for polymeric luminescence materials. They are also preferred because they have a boiling point equal to or less than 180° C. under atmospheric pressure and, therefore, can be easily handled and also can be easily removed after the organic luminescence layer has been formed. A surfactant, an antioxidant, a UV absorber, and a viscosity-adjusting agent may be added, as necessary, to the organic luminescence coating liquid.

Other examples include well-known fluorescent small-molecular materials that can emit light from a singlet state, such as materials of a coumarin system, a perylene system, a pyran system, an anthrone system, a porphylene system, a quinacridone system, an N,N′-dialkyl-substituted quinacridone system, naphthalimide system, and an N,N′-diaryl-substituted pyrrolopyrrole system and well-known phosphorescent small-molecular materials that can emit light from a triplet state of a rare earth metal complex. These materials can be used to form an organic luminescence layer by a dry process such as vacuum vapor deposition.

Further, the organic luminescence layer 103b can be also formed by a wet process by using an organic luminescence coating liquid prepared by dissolving or dispersing the above-described materials in an individual or mixed solvent such as toluene, xylene, acetone, anisole, methyl anisole, dimethyl anisole, ethyl benzoate, methyl benzoate, mesitylene, tetralin, amyl benzene, methyl ethyl ketone, methyl isobutyl ketone, cyclohexanone, methanol, ethanol, isopropyl alcohol, ethyl acetate, butyl acetate, cyclohexanol, and water.

A material emitting light of the same color can be arranged as the organic luminescence layer 103b provided in each pixel location, and in this case a monochromatic display device is obtained. When a color screen is to be displayed, a color filter has to be provided or organic luminescence layers 103b that emit light of different colors have to be arranged in a pattern in respective pixel locations. The colors of such organic luminescence layers 103b that emit light of mutually different colors are red (R), green (G), and blue (B), which are equivalent to three primary colors of light. Further, yellow (Y), cyan (C), and magenta (M), which are equivalent to auxiliary colors, are sometimes also used.

When the organic luminescence layer 103b is formed by a wet printing method using a coating liquid, the coating can be performed by a printing method such as a relief printing method, an intaglio printing method, a screen printing method, a gravure printing method, a flexo printing method, an offset printing method, and an ink-jet method, but the relief printing method is especially preferred for fabricating organic EL elements because such method is suitable in a viscous region of organic luminescence coating liquids, makes it possible to preform printing without damaging the substrate, and has a high utilization efficiency of material.

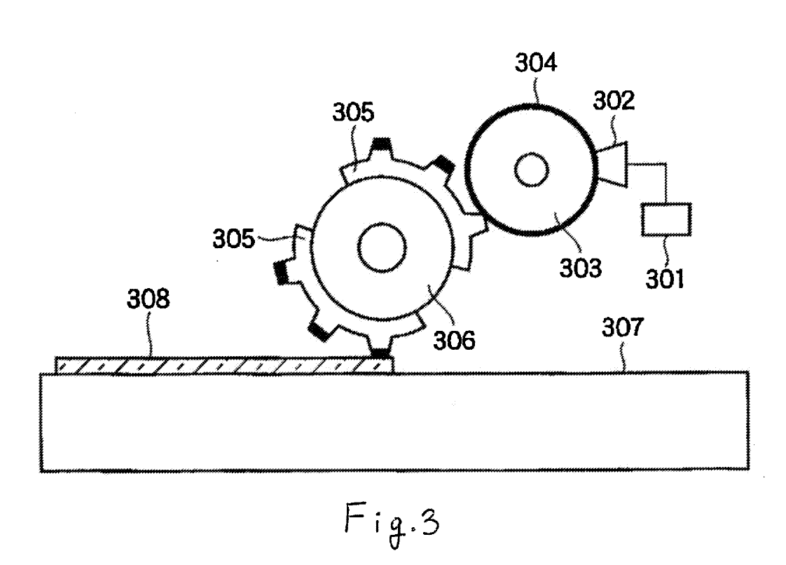

FIG. 3 illustrates the relief printing method. A device used for relief printing illustrated by FIG. 3 has an ink tank 301, an ink chamber 302, an anilox roll 303 that receives an ink 304 from the ink chamber 302, and a plate body 306 having attached thereto a relief plate 305 for printing. A coating liquid of an organic luminescence material is accommodated in the ink tank 301, and the coating liquid is fed from the ink tank 301 into the ink chamber 302. The anilox roll 303 rotates in contact with an ink supply unit of the ink chamber 302 and the relief plate 305 for printing.

As the anilox roll 303 rotates, the ink 304 supplied from the ink chamber 302 is uniformly held on the surface of the anilox roll 303 and then transferred as a film of uniform thickness onto the convexities of the relief plate 305 for printing that is attached to the plate body 306. Further, a printing substrate 308 is fixed onto a slidable substrate fixing base 307 and moved to a printing start position, while the positions of the plate pattern and substrate pattern are adjusted by a position adjustment mechanism. The substrate is then moved according to the rotation of the plate body 306, while the convexities of the relief plate 305 for printing come into contact with the substrate 308, and the ink pattern is transferred onto the predetermined positions of the printing substrate 308.

A drying process is necessary after the film forming process performed by a wet method. A drying method based on heating or evacuation can be selected, provided that the solvent can be removed to a degree such that light emission characteristic are not degraded. Taking into account the heat-induced deterioration of the luminescence medium layer 103, it is preferred that heating be performed at a temperature equal to or lower than the Tg of the luminescence medium material, and solvent removal performed under vacuum is even more preferred.

Materials that have been generally used as electron transport materials may be used as organic hole blocking materials and electron transport materials that can be employed in the hole blocking layer and electron transport layer. Examples of suitable materials include small-molecular materials of a triazole system, an oxazole system, an oxadiazole system, a silole system, and a boron system, and the film can be formed by a vacuum vapor deposition method. An electron transport coating liquid can be obtained by dispersing these electron transport materials in a polymer such as polystyrene, polymethyl methacrylate, or polyvinyl carbazole, or by dissolving or dispersing in an individual or mixed solvent such as toluene, xylene, acetone, methyl ethyl ketone, methyl isobutyl ketone, cyclohexanone, methanol, ethanol, isopropyl alcohol, ethyl acetate, butyl acetate, and water, and the film can be formed by a wet method such as printing.

Examples of materials that are suitable as electron injection materials that can be used for the electron injection layer include materials identical to those used in the above-described electron transfer layer and also salts of alkali metals and alkaline earth metals and oxides (alkali metal or alkaline earth metal oxides) such as lithium fluoride and lithium oxide, and the film can be formed by vacuum vapor deposition. An electron injection coating liquid can be obtained by dispersing these electron injection materials in a polymer such as polystyrene, polymethyl methacrylate, or polyvinyl carbazole, or by dissolving or dispersing in an individual or mixed solvent such as toluene, xylene, acetone, methyl ethyl ketone, methyl isobutyl ketone, cyclohexanone, methanol, ethanol, isopropyl alcohol, ethyl acetate, butyl acetate, and water, and the film can be formed by a wet method such as printing.

When these layers are formed by a printing method, the coating can be performed by a printing method such as a relief printing method, an intaglio printing method, a screen printing method, a gravure printing method, a flexo printing method, an offset printing method, and an ink-jet method, but the relief printing method is especially preferred for fabricating organic EL elements because such method is suitable in a viscous region of organic luminescence coating liquids, makes it possible to preform printing without damaging the substrate, and has a high utilization efficiency of material.

A single metal such as Mg, Al, and Yb can be used for the second electrode 104, which is a counter electrode. In order to ensure both the electron injection efficiency and the stability, alloys system of a metal with a low work function and a stable metal, for example, MgAg, AlLi, CuLi can be used. According to the type of material used, a resistance heating and vapor deposition method, an electron beam method, and a sputtering method can be employed for forming the second electrode 104. The thickness of the second electrode 104 is preferably about 10 nm to 1000 nm.

Finally, in order to protect the organic EL laminated body from external oxygen or moisture, it can be air-tightly sealed using a glass cap and an adhesive to obtain an organic EL element. When the translucent substrate 101 is flexible, air-tight sealing is performed using a sealing agent and a flexible film.

In FIG. 1, the lamination on the translucent substrate 101 is started with the first electrode 102 serving as an anode, but the lamination started from the first electrode 102 as a cathode can be also appropriately performed.

Further, in FIG. 1, the side of the substrate 101 is a display side, but the display can be also appropriately performed from the side opposite to that of the substrate 101.

In accordance with the present invention, by performing an oxidation treatment after a film of an inorganic oxide has been formed makes it possible to obtain a highly reliable organic EL element that has carrier transport layers having the desired electric conductivity and transmissivity and can be manufactured by a simpler process because the wettability of the inorganic oxide layer is improved. Because the organic EL element has the desired electric conductivity and transmissivity, a higher emission luminance of organic EL can be obtained.

### EXAMPLES

Examples of the organic EL element in accordance with the present invention will be described below, but the present invention is not limited to the below-described examples.

### Example 1

As shown in FIG. 1, a rectangular glass substrate with a thickness of 0.7 mm and a length of one side of 100 mm was used as a translucent substrate 101. A transparent electrically conductive layer was formed on the substrate 101 by sputtering ITO. Then, ITO lines with a pitch of 800 μm (L/S=700/100) were patterned by photolithography, and a translucent first electrode 102 was obtained. In order to cover the end portions of the patterned ITO lines, patterning was performed by photolithography and insulating ribs 205 were provided so as to cover the end portions of the patterns of the adjacent transparent electrodes 202.

A film of vanadium pentoxide V₂O₅ with a thickness of 70 nm was then formed as a hole transport layer 103a by a vacuum vapor deposition method, and then an oxidation treatment was performed for 20 sec under an oxygen gas pressure of 0.003 Torr and a supplied power of 100 W by using an oxygen plasma device. The transmissivity of a hole transport layer 103a thus obtained was 93% (550 nm), and the electric conductivity was 6.90×10⁻³ S/cm.

The transmissivity was measured using a device UV-3100 manufactured by Shimadzu Corp. in the air with respect to a V₂O₅ film that was vapor deposited on a quartz substrate and subjected to an oxidation treatment. The electric conductivity was measured by a four-terminal method by using a resistant meter MCP-T610 manufactured by Dia Instruments Co., Ltd.

The surface of the obtained vanadium pentoxide V₂O₅ was analyzed under the following conditions with an XPS device ESCA5500MT manufactured by ULVAC-PHI, Inc. The peak ratio of V and O was 2:4.2.

### <XPS Device Conditions>

X ray source: MgKα (15 kV-200 W).

Take-out angle: 15-90 degrees (uniformity is confirmed by angle resolution measurements).

Analyzed area: diameter 0.8 mm.

Pass energy: 23.5 eV.

Number of integrations: 20-50.

Electrostatic correction: correction for C1s=285.0 eV.

A coating liquid containing 1 vol. % a PPV-type polymer material that is an organic luminescence material, 84 vol. % toluene as a solvent, and 15 vol. % anisole was then prepared, and an organic luminescence layer 103b was obtained by patterning for RGB colors by a relief printing method. Finally, MgAg was vapor deposited as a counter electrode 104 by a two-element vapor deposition method, and lines with a pitch of 800 μm (L/S=700/100) and a thickness of 150 nm were patterned by photolithography to obtain stripes perpendicular to the translucent first electrode 101. Air-tight sealing was then performed using a glass cap and an adhesive, and an organic EL element of a passive drive type was produced.

Light emission with a luminance of 1000 cd/m² could be obtained at a drive voltage of 4.5 V in the obtained passive organic EL element, and the emission efficiency of the element was 12.0 cd/A. Further, only the selected pixel emitted light and no emission leak caused by electric current leak was observed.

The emission luminance mentioned above was measured using BM7 manufactured by Topcon. The emission efficiency was found from the aforementioned emission luminance and electric current value in the case of driving with TR6143 manufactured by Advantest Corp.

### Example 2

In Example 2, as shown in FIG. 1, molybdenum trioxide was vacuum vapor deposited to a thickness of 30 nm as a hole transport layer 103a, and a thermal oxidation treatment was conducted in dry air for about 2 hours at 250° C. Other conditions were identical to those of Example 1. The transmissivity of the obtained hole transport layer 103a was 91% (550 nm) and the electric conductivity was 5.60×10⁻⁴ S/cm.

The surface of the MoO₃ obtained was analyzed with the XPS device in the same manner as in Example 1 and a peak ratio of Mo and O was 1:2.6.

Light emission with a luminance of 1000 cd/m² could be obtained at a drive voltage of 4.0 V in the passive organic EL element obtained in the same manner as in Example 1, and the emission efficiency of the element was 10.0 cd/A. Further, only the selected pixel emitted light and no emission leak caused by electric current leak was observed.

### Example 3

In Example 3, as shown in FIG. 1, molybdenum trioxide MoO₃ was sputtered to a thickness of 30 nm as a hole transport layer 103a, and an oxidation treatment was conducted for about 20 sec under an oxygen gas pressure of 0.002 Torr and a supplied electric power of 100 W by using an oxygen plasma device. Other conditions were identical to those of Example 1. The transmissivity of the obtained hole transport layer 103a was 95% (550 nm) and the electric conductivity was 1.10×10⁻⁵ S/cm.

The surface of the MoO₃ obtained was analyzed with the XPS device in the same manner as in Example 1 and a peak ratio of Mo and O was 1:2.7.

Light emission with a luminance of 1000 cd/m² could be obtained at a drive voltage of 4.2 V in the passive organic EL element obtained in the same manner as in Example 1, and the emission efficiency of the element was 12.0 cd/A. Further, only the selected pixel emitted light and no emission leak caused by electric current leak was observed.

### Example 4

In Example 4, as shown in FIG. 2, molybdenum trioxide MoO₃ was vacuum vapor deposited to a thickness of 30 nm as a hole transport layer 203a and patterned with a mask, and a thermal oxidation treatment was conducted in dry air for about 2 hours at 250° C. Other conditions were identical to those of Example 1. The transmissivity of the obtained hole transport layer 203a was 91% (550 nm) and the electric conductivity was 5.60×10⁻⁴ S/cm.

The surface of the MoO₃ obtained was analyzed with the XPS device in the same manner as in Example 1 and a peak ratio of Mo and O was 1:2.6.

Light emission with a luminance of 1000 cd/m² could be obtained at a drive voltage of 4.0 V in the passive organic EL element obtained in the same manner as in Example 1, and the emission efficiency of the element was 10.0 cd/A. Further, only the selected pixel emitted light and no emission leak caused by electric current leak was observed.

### Example 5

In Example 5, molybdenum trioxide MoO₃ was vacuum vapor deposited to a thickness of 30 nm as a hole transport layer 103a as shown in FIG. 1, and UV irradiation was performed for 10 min at an ozone concentration of 100±50 ppm, a UV intensity of 10.0 mW/cm² (254 nm), and an irradiation distance of 20 mm by using an ultraviolet irradiation device (a low-pressure mercury lamp was used). Other conditions were identical to those of Example 1. The transmissivity of the obtained hole transport layer 103a was 89% (550 nm) and the electric conductivity was 7.30×10⁻⁴ S/cm.

The surface of the MoO₃ obtained was analyzed with the XPS device in the same manner as in Example 1 and a peak ratio of Mo and O was 1:2.5.

Light emission with a luminance of 1000 cd/m² could be obtained at a drive voltage of 4.2 V in the passive organic EL display panel obtained in the same manner as in Example 1, and the emission efficiency of the element was 11.0 cd/A. No unevenness was observed in the displayed image, the image was very sharp, and no crosstalk was observed.

Where an organic luminescence layer was printed on the hole transport layer in Examples 1 to 5, uniform printing without the occurrence of peeling could be performed.

The transmissivity, electric conductivity, XPS analysis values, drive voltage, and efficiency obtained in Examples 1 to 5 are shown in a table below.

TABLE 1

| | | | Film | | | Electric | XPS | Drive voltage | Current efficiency |
|---|---|---|---|---|---|---|---|---|---|
| | | Manuf. | thickn. | Oxidation | Transmissivity | conductivity | V:O or | at 1000 cd/m² | at 1000 cd/m² |
| | Material | method | (nm) | treatment | (% @550 nm) | (S/cm) | Mo:O | (V) | (cd/A) |
| Example | | | | | | | | | |
| 1 | V₂O₅ | Vapor | 70 | Oxygen | 93 | 6.90E−03 | 2:4.2 | 4.5 | 12.0 |
| | | deposition | | plasma | | | | | |
| 2 | MoO₃ | Vapor | 30 | Thermal | 91 | 5.60E−04 | 1:2.6 | 4.0 | 10.0 |
| | | deposition | | oxidation | | | | | |
| | | | | (250° C., 2 h) | | | | | |
| 3 | MoO₃ | Sputtering | 30 | Oxygen | 95 | 1.10E−05 | 1:2.7 | 4.2 | 12.0 |
| | | | | plasma | | | | | |
| 4 | MoO₃ | Vapor | 30 | Thermal | 91 | 5.60E−04 | 1:2.6 | 4.0 | 10.0 |
| | | deposition | | oxidation | | | | | |
| | | | | (250° C., 2 h) | | | | | |
| 5 | MoO₃ | Vapor | 30 | UV | 89 | 7.30E−04 | 1:2.5 | 4.2 | 11.0 |
| | | deposition | | | | | | | |
| Compar. | | | | | | | | | |
| example | | | | | | | | | |
| 1 | V₂O₅ | Vapor | 70 | No | 79 | 4.10E−02 | 2:3.7 | 4.2 | 4.0 |
| | | deposition | | treatment | | | | | |
| 2 | MoO₃ | Vapor | 30 | No | 85 | 1.60E−03 | 1:2.3 | 3.4 | 5.0 |
| | | deposition | | treatment | | | | | |
| 3 | MoO₃ | Sputtering | 30 | No | 91 | 9.90E−04 | 1:2.4 | 4.1 | 10.0 |
| | | | | treatment | | | | | |
| 4 | MoO₃ | Vapor | 30 | No | 85 | 1.60E−03 | 1:2.3 | 3.3 | 7.2 |
| | | deposition | | treatment | | | | | |
| 5 | MoO₃ | Vapor | 30 | No | 85 | 1.60E−03 | 1:2.3 | 3.4 | 5.0 |
| | | deposition | | treatment | | | | | |

### Comparative Example 1

A film obtained by vacuum vapor depositing vanadium pentoxide V₂O₅ to a thickness of 70 nm was used as a hole transport layer, and no oxidation treatment was performed. Other conditions were identical to those of Example 1. The transmissivity of the obtained hole transport layer was 79% nm) and the electric conductivity was 4.10×10⁻² S/cm. The surface of the V₂O₅ obtained was analyzed with the XPS device in the same manner as in Example 1 and a peak ratio of V and O was 2:3.7.

In the passive organic EL element obtained in the same manner as in Example 1 by using this hole transport layer, light emission with a luminance of 1000 cd/m² could be obtained at a drive voltage of 4.2 V, and the emission efficiency of the element was 4.0 cd/A. Emission leak caused by leak electric current was confirmed. The number of oxygen defects in the hole transport layer was larger than that in Example 1, and the decrease in drive voltage demonstrated that holes could easily flow in the film. However, the emission efficiency itself decreased due to excess in the holes, and the element service life was short. Further, the obtained hole transport layer had a low transmissivity, and a loss in light take-out zones was high.

### Comparative Example 2

A film obtained by vacuum vapor depositing molybdenum trioxide MoO₃ to a thickness of 30 nm was used as a hole transport layer, and no oxidation treatment was performed. Other conditions were identical to those of Example 2. The transmissivity of the obtained hole transport layer was 85% (550 nm) and the electric conductivity was 1.60×10⁻³ S/cm. The surface of the MoO₃ obtained was analyzed with the XPS device in the same manner as in Example 2 and a peak ratio of Mo and O was 1:2.3.

In the passive organic EL element obtained in the same manner as in Example 2, light emission with a luminance of 1000 cd/m² could be obtained at a drive voltage of 3.4 V, and the emission efficiency of the element was 5.0 cd/A. Emission leak caused by leak electric current was confirmed. The number of oxygen defects in the hole transport layer was larger than that in Example 2, and the decrease in drive voltage demonstrated that holes could easily flow in the film. However, the emission efficiency itself decreased due to excess in the holes, and the element service life was short. Further, the obtained hole transport layer had a low transmissivity, and a loss in light take-out zones was high.

### Comparative Example 3

A film obtained by sputtering molybdenum trioxide MoO₃ to a thickness of 30 nm was used as a hole transport layer, and no oxidation treatment was performed. Other conditions were identical to those of Example 3. The transmissivity of the obtained hole transport layer was 91% (550 nm) and the electric conductivity was 9.90×10⁻⁴ S/cm. The surface of the obtained was analyzed with the XPS device in the same manner as in Example 3 and a peak ratio of Mo and O was 1:2.4.

In the passive organic EL element obtained in the same manner as in Example 3, light emission with a luminance of cd/m² could be obtained at a drive voltage of 4.1 V, and the emission efficiency of the element was 10.0 cd/A. In this case, emission leak caused by leak electric current was not confirmed, but the transmissivity of the hole transport layer was lower than that in Example 3. As a result, a loss in light take-out zones was high.

### Comparative Example 4

A film obtained by vacuum vapor depositing molybdenum trioxide MoO₃ to a thickness of 30 nm with patterning using a mask was employed as a hole transport layer (see FIG. 2), and no oxidation treatment was performed. Other conditions were identical to those of Example 4. The transmissivity of the obtained hole transport layer was 85% (550 nm) and the electric conductivity was 1.60×10⁻³ S/cm. The surface of the MoO₃ obtained was analyzed with the XPS device in the same manner as in Example 4 and a peak ratio of Mo and O was 1:2.3.

In the passive organic EL element obtained in the same manner as in Example 4, light emission with a luminance of 1000 cd/m² could be obtained at a drive voltage of 3.3 V, and the emission efficiency of the element was 7.2 cd/A. Because the hole transport layer was patterned for each pixel, emission leak did not occur and both the drive voltage and the emission efficiency were improved over those of Comparative Example 2 in which the hole transport layer was provided over the entire surface. However, loss of luminance and efficiency caused by decrease in transmissibility with respect to those of Example 4 were obvious.

### Comparative Example 5

A film obtained by vacuum vapor depositing molybdenum trioxide MoO₃ to a thickness of 30 nm was used as a hole transport layer, and no UV treatment was performed after the film has been formed. Other conditions were identical to those of Example 5.

The transmissivity of the obtained hole transport layer was 85% (550 nm) and the electric conductivity was 1.60×10⁻³ S/cm. The surface of the MoO₃ obtained was analyzed with the XPS device in the same manner as in Example 5 and a peak ratio of Mo and O was 1:2.3. When an organic luminescence layer was printed on the molybdenum trioxide MoO₃, peeling occurred and uniform printing could not be performed.

In the passive organic EL display panel obtained in the same manner as in Example 5, light emission with a luminance of 1000 cd/m² could be obtained at a drive voltage of 3.4 V, and the emission efficiency in this case was 5.0 cd/A. By contrast with Example 5, emission unevenness was observed and crosstalk has occurred.

The transmissivity, electric conductivity, XPS analysis values, drive voltage, and efficiency obtained in Comparative Examples 1 to 5 are shown in the table above.

What is claimed is:

1. An organic EL element comprising:
a first electrode;
a second electrode facing the first electrode; and
a luminescence medium layer comprising a carrier transport layer and an organic luminescence layer disposed between the electrodes; wherein
the carrier transport layer is an inorganic oxide layer obtained by performing an oxidation treatment after forming the layer.

2. The organic EL element according to claim 1, wherein
the carrier transport layer is a hole transport layer.

3. The organic EL element according to claim 1, wherein
the oxidation treatment is an oxygen plasma treatment.

4. The organic EL element according to claim 1, wherein
the oxidation treatment is a thermal oxidation treatment.

5. The organic EL element according to claim 1, wherein
the oxidation treatment is a UV treatment.

6. The organic EL element according to claim 1, wherein
the inorganic oxide of the inorganic oxide layer is a transition metal oxide.

7. The organic EL element according to claim 6, wherein
the transition metal oxide is a molybdenum oxide.

8. The organic EL element according to claim 6, wherein
the transition metal oxide is a vanadium oxide.

9. The organic EL element according to claim 1, wherein
the first electrode has patterns, and insulating ribs are provided so as to cover end portions of adjacent patterns.

10. The organic EL element according to claim 9, wherein
the inorganic oxide is disposed between the insulating ribs.

11. The organic EL element according to claim 9, wherein
the inorganic oxide is continuously disposed between the insulating ribs and on the insulating ribs.

12. A method for manufacturing an organic EL element comprising a first electrode; a second electrode facing the first electrode; and a luminescence medium layer comprising a carrier transport layer and an organic luminescence layer disposed between the electrodes, the method comprising forming an inorganic oxide layer as the carrier transport layer and subjecting the inorganic oxide layer to an oxidation treatment.

13. The method for manufacturing an organic EL element according to claim 12, further comprising forming the organic luminescence layer by a wet film forming method after the inorganic oxide layer has been subjected to the oxidation treatment.

14. The method for manufacturing an organic EL element according to claim 13, wherein
the wet film forming method is a printing method.

15. A display device comprising
the organic EL element according to claim 1.
